(19) United States
(12) Patent Application Publication
(10) Pub. No.: US 2025/0111117 A1
(43) Pub. Date: Apr. 3, 2025

(54) Simultaneous Configuration of Programmable Logic Fabric and Disaggregated Dies

(71) Applicant: Intel Corporation, Santa Clara, CA (US)

(72) Inventors: Han Hua Leong, Butterworth (MY); Ting Ting Teh, San Jose, CA (US)

(21) Appl. No.: 18/478,537

(22) Filed: Sep. 29, 2023

(51) Int. Cl. G06F 30/34

(52) U.S. Cl. CPC G06F 30/34

(57) ABSTRACT

Integrated circuit devices, methods, and circuitry that program disaggregated dies and programmable logic devices at least partially in parallel are described herein. A host device may program a programmable logic device using a configuration bitstream having a first protocol and sent via a first portion (e.g., first layer) of a communication link. The host device may program disaggregated dies using image files having a second protocol and sent via a second portion (e.g., second layer) of a communication link. The host device may send the configuration data and the image files at a same or overlapping time since the data may be sent in separate layers of the communication link, thereby avoiding interference.

### BACKGROUND

This disclosure relates to disaggregated system architectures that may enable improved configuration operations.

This section is intended to introduce the reader to various aspects of art that may be related to various aspects of the present disclosure, which are described and/or claimed below. This discussion is believed to be helpful in providing the reader with background information to facilitate a better understanding of the various aspects of the present disclosure. Accordingly, it may be understood that these statements are to be read in this light, and not as admissions of prior art.

Integrated circuits are found in numerous electronic devices and provide a variety of functionality. For example, programmable logic circuitry in a programmable logic device, such as a field programmable gate array (FPGA), may be used to perform a variety of operations and offer relatively high amounts of computational flexibility relative to hard logic unable to reprogrammed. Dies or devices may be coupled to the programmable logic device. However, to program the dies or devices, configuration data may be routed through the programmable logic device. Routing the configuration data through the programmable logic device may increase delays, causing slowed boot times and reducing an efficiency of configuration methods.

### BRIEF DESCRIPTION OF THE DRAWINGS

Various aspects of this disclosure may be better understood upon reading the following detailed description and upon reference to the drawings in which:

FIG. 1 is a block diagram of a system used to program an integrated circuit device;

FIG. 2 is a block diagram of the integrated circuit device of FIG. 1;

FIG. 3 is a block diagram of the integrated circuit device of FIG. 1 (e.g., programmable logic device, field programmable gate array (FPGA)) that includes circuitry to program disaggregated dies in parallel with the integrated circuit device of FIG. 1;

FIG. 4 is a diagrammatic representation of a process performed via the host device of FIG. 1 and the integrated circuit device of FIG. 1 to configure (re) programmable logic circuitry of the integrated circuit device of FIG. 1 in parallel to programming the disaggregated dies of FIG. 3;

FIG. 5 is a flowchart of a process performed by the host device of FIG. 1 to program the disaggregated dies of FIG. 3 in parallel to (re) programmable logic circuitry configuration of the integrated circuit device of FIG. 1;

FIG. 6 is a flowchart of a process performed by the integrated circuit device of FIG. 1 to program one or more of the disaggregated dies or devices of FIG. 3 in parallel to programming its (re) programmable logic circuitry; and

FIG. 7 is a block diagram of a data processing system that may incorporate the integrated circuit of FIG. 1 with a host processor.

### DETAILED DESCRIPTION OF SPECIFIC EMBODIMENTS

One or more specific embodiments will be described below. In an effort to provide a concise description of these embodiments, not all features of an actual implementation are described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

When introducing elements of various embodiments of the present disclosure, the articles “a,” “an,” and “the” are intended to mean that there are one or more of the elements. The terms “comprising,” “including,” and “having” are intended to be inclusive and mean that there may be additional elements other than the listed elements. Additionally, it should be understood that references to “one embodiment” or “an embodiment” of the present disclosure are not intended to be interpreted as excluding the existence of additional embodiments that also incorporate the recited features.

A disaggregated system may include one or more programmable logic devices, such as a field programmable gate array (FPGA), coupled to one or more disaggregated dies, where a respective disaggregated die may correspond to a separate or external device, a chiplet, a separately packaged die, or the like. Disaggregated systems may enable processing operations to be decentralized from the programmable logic device and distributed across the disaggregated dies. For example, the programmable logic device may offload processing operations to a respective disaggregated die and use a result or data received from that respective disaggregated die to complete another processing operation. In some systems, the programmable logic device may not offload operations and may operate based on results or data received from the disaggregated data. Disaggregated systems may improve manufacturing complexity by enabling packaged systems (e.g., separately packaged die, separately developed module of a device) to be used in conjunction with the programmable logic device, which may reduce computing resources spent programming the programmable logic device, reduce processing times by enabling parallel processing to occur, and reduce a complexity of systems to provide each desired operation of the programmable logic device.

Although using disaggregated systems may be desired, programming a disaggregated system is complicated by how configuration data may be routed through the programmable logic device. Routing configuration data through the programmable logic device may increase a total time spent programming and/or booting the disaggregated system since, as an example, the programmable logic device soft logic may be programmed then used to program any other dies or devices. Systems and methods described herein may improve disaggregated system configuration operations by enabling programming of the programmable logic device to occur in parallel with programming of the dies or devices. Indeed, these systems and methods described herein are based on using a first protocol and a second protocol to enable the parallel programming. Configuration may be based on Compute Express Link (CXL) interconnect communications, Peripheral Component Interconnect Express (PCIe or PCI-E) communications, or the like. CXL interconnect may provide the host device access to configuration registers and control interfaces of coupled disaggregated dies/devices via the programmable logic device, which may be simultaneously undergoing configuration via a Peripheral Component Interconnect Express (PCIe or PCI-E) bus.

Indeed, systems and methods described herein involve host device-managed simultaneous programming operations where a programmable logic device and its disaggregated dies/devices may be programmed at least partially in parallel (e.g., simultaneously). The host device may perform these configuration operations before entering a user mode. Configuration or programming of components may occur based on CXL and may be used in systems that use a programmable logic device to couple with other disaggregated components like die-die interconnect via Universal Chiplet Interconnect Express (UCIe) (where CXL may be supported) or device-to-device via CXL. By configuring the dies or devices using first communications (e.g., CXL communications), configuration of the programmable logic device using second communications (e.g., PCIe communications, CXL communications) may occur in parallel. Performing configurations in parallel may enable reduced (e.g., faster) boot times and/or reduced computing cycle arising from a reduced complexity of the disaggregated system. Additional benefits may arise from being able to perform inline programming to reduce programmable logic device pin counts used when configuring the disaggregated system architecture. Indeed, these systems and methods may reduce pin count since sideband configuration (e.g., Joint Test Action Group interface (JTAG), packet switching serial communication bus (I2C), serial peripheral interface (SPI), quad SPI (QSPI), controller area network (CAN), universal asynchronous receiver/transmitter (UART) bus, or other custom configuration interface or bus) for disaggregated dies/devices may be managed by host device directly without using the sideband interface to transmit the sideband configuration. Additional benefits may arise from reducing complexity by enabling operations to be executed on both the host device and the programmable logic device, which may help unify software development and integration, as well as improve interoperability of heterogeneous components (e.g., processors, accelerators, memory devices) within the disaggregate system.

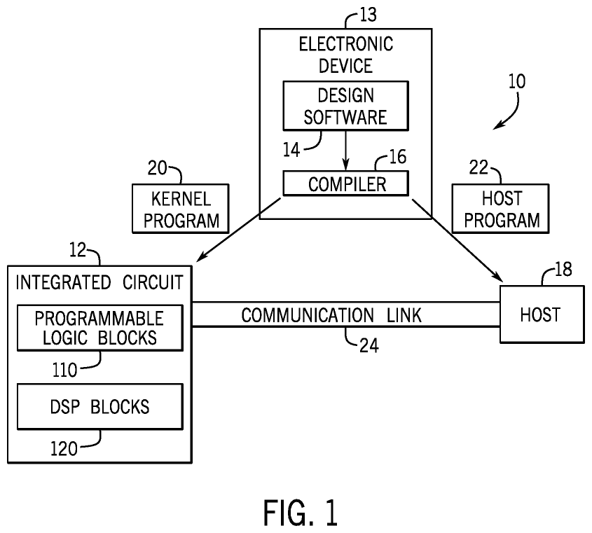

With the foregoing in mind, FIG. 1 illustrates a block diagram of a system 10 that may be used in configuring an integrated circuit 12 with such a digital signal processing (DSP) block. A designer may desire to implement testbench functionality on the integrated circuit 12 (e.g., a programmable logic device such as a field-programmable gate array (FPGA) or an application-specific integrated circuit (ASIC) that includes programmable logic circuitry). The integrated circuit 12 may include a single integrated circuit, multiple integrated circuits in a package, or multiple integrated circuits in multiple packages communicating remotely (e.g., via wires or traces). In some cases, the designer may specify a high-level program to be implemented, such as an OPENCL® program that may enable the designer to more efficiently and easily provide programming instructions to configure a set of programmable logic cells for the integrated circuit 12 without specific knowledge of low-level hardware description languages (e.g., Verilog, very high speed integrated circuit hardware description language (VHDL)). For example, since OPENCL® is quite similar to other high-level programming languages, such as C++, designers of programmable logic familiar with such programming languages may have a reduced learning curve than designers that are required to learn unfamiliar low-level hardware description languages to implement new functionalities in the integrated circuit 12.

In a configuration mode of the integrated circuit 12, a designer may use an electronic device 13 (e.g., a computer) to implement high-level designs (e.g., a system user design) using design software 14, such as a version of INTEL® QUARTUS® by INTEL CORPORATION. The electronic device 13 may use the design software 14 and a compiler 16 to convert the high-level program into a lower-level description (e.g., a configuration program, a bitstream). The compiler 16 may provide machine-readable instructions representative of the high-level program to a host 18 and the integrated circuit 12. The host 18 may receive a host program 22 that may be implemented by the kernel programs 20. To implement the host program 22, the host 18 may communicate instructions from the host program 22 to the integrated circuit 12 via a communications link 24 (e.g., data channel) that may be, for example, direct memory access (DMA) communications or peripheral component interconnect express (PCIe) communications. In some embodiments, the kernel programs 20 and the host 18 may enable configuration of programmable logic blocks 110 (e.g., programmable logic fabric, programmable logic) on the integrated circuit 12. The programmable logic blocks 110 may include circuitry and/or other logic elements and may be configurable to implement a variety of functions, such as data filtering or processing operations, in combination with digital signal processing (DSP) blocks.

The designer may use the design software 14 to generate and/or to specify a low-level program, such as the low-level hardware description languages described above. Further, in some embodiments, the system 10 may be implemented without a separate host program 22. Thus, embodiments described herein are intended to be illustrative and not limiting.

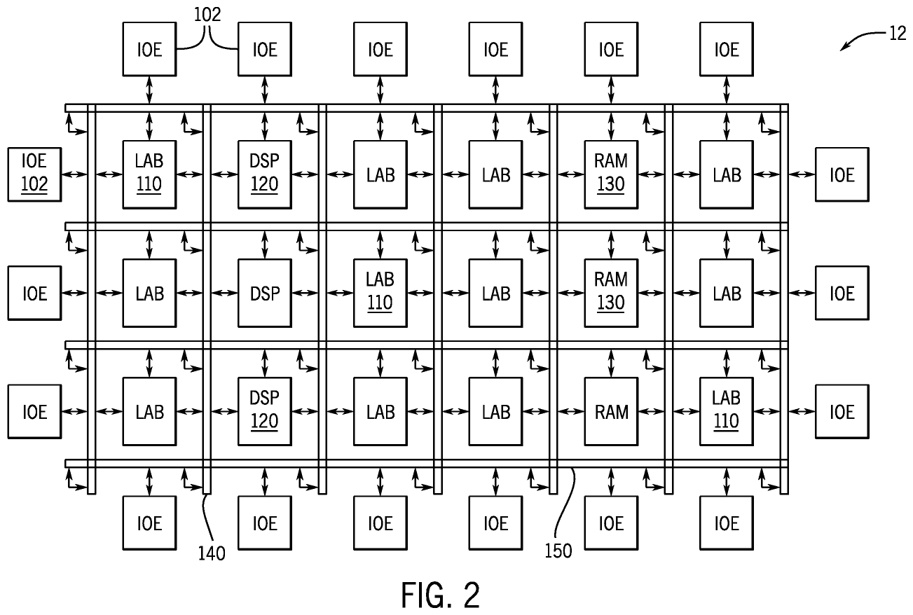

An illustrative embodiment of a programmable integrated circuit 12 such as a programmable logic device (PLD) that may be programmed to implement a circuit design is shown in FIG. 2. As shown in FIG. 2, the integrated circuit 12 (e.g., a field-programmable gate array integrated circuit die) may include a two-dimensional array of functional blocks, including programmable logic blocks 110 (also referred to as logic array blocks (LABs) or configurable logic blocks (CLBs)) and other functional blocks, such as random-access memory (RAM) blocks 130 and digital signal processing (DSP) blocks 120, for example. Functional blocks such as LABs 110 may include smaller programmable regions (e.g., logic elements, configurable logic blocks, or adaptive logic modules) that receive input signals and perform custom functions on the input signals to produce output signals. LABs 110 may also be grouped into larger programmable regions sometimes referred to as logic sectors that are individually managed and programmed by corresponding logic sector managers. The grouping of the programmable logic resources on the integrated circuit 12 into logic sectors, logic array blocks, logic elements, or adaptive logic modules is merely illustrative. In general, the integrated circuit 12 may include functional logic blocks of any suitable size and type, which may be organized in accordance with any suitable logic resource hierarchy.

Programmable logic of the integrated circuit 12 may include programmable memory elements, and thus may be considered a programmable logic device (PLD). Memory elements may be loaded with configuration data (also called programming data or configuration bitstream) using input-output elements (IOEs) 102. Once loaded, the memory elements each provide a corresponding static control signal that controls the operation of an associated functional block (e.g., LABs 110, DSP 120, RAM 130, or input-output elements 102).

In one scenario, the outputs of the loaded memory elements are applied to the gates of metal-oxide-semiconductor transistors in a functional block to turn certain transistors on or off and thereby configure the logic in the functional block including the routing paths. Programmable logic circuit elements that may be controlled in this way include parts of multiplexers (e.g., multiplexers used for forming routing paths in interconnect circuits), look-up tables, logic arrays, AND, OR, NAND, and NOR logic gates, pass gates, etc.

The memory elements may use any suitable volatile and/or non-volatile memory structures such as random-access-memory (RAM) cells, fuses, antifuses, programmable read-only-memory memory cells, mask-programmed and laser-programmed structures, combinations of these structures, etc. Because the memory elements are loaded with configuration data during programming, the memory elements are sometimes referred to as configuration memory, configuration random-access memory (CRAM), or programmable memory elements. The integrated circuit 12 as a programmable logic device (PLD) may implement a custom circuit design. For example, the configuration RAM may be programmed such that LABs 110, DSP 120, and RAM 130, programmable interconnect circuitry (i.e., vertical channels 140 and horizontal channels 150), and the input-output elements 102 form the circuit design implementation.

In addition, the programmable logic device may have input-output elements (IOEs) 102 for driving signals off of the integrated circuit 12 and for receiving signals from other devices. Input-output elements 102 may include parallel input-output circuitry, serial data transceiver circuitry, differential receiver and transmitter circuitry, or other circuitry used to connect one integrated circuit to another integrated circuit.

The integrated circuit 12 may also include programmable interconnect circuitry in the form of vertical routing channels 140 (i.e., interconnects formed along a vertical axis of the integrated circuit 12) and horizontal routing channels 150 (i.e., interconnects formed along a horizontal axis of the integrated circuit 12), each routing channel including at least one track to route at least one wire. If desired, the interconnect circuitry may include pipeline elements, and the contents stored in these pipeline elements may be accessed during operation. For example, a programming circuit may provide read and write access to a pipeline element.

Note that other routing topologies, besides the topology of the interconnect circuitry depicted in FIG. 1, are intended to be included within the scope of the present disclosure. For example, the routing topology may include wires that travel diagonally or that travel horizontally and vertically along different parts of their extent as well as wires that are perpendicular to the device plane in the case of three-dimensional integrated circuits, and the driver of a wire may be located at a different point than one end of a wire. The routing topology may include global wires that span substantially all of the integrated circuit 12, fractional global wires such as wires that span part of the integrated circuit 12, staggered wires of a particular length, smaller local wires, or any other suitable interconnection resource arrangement.

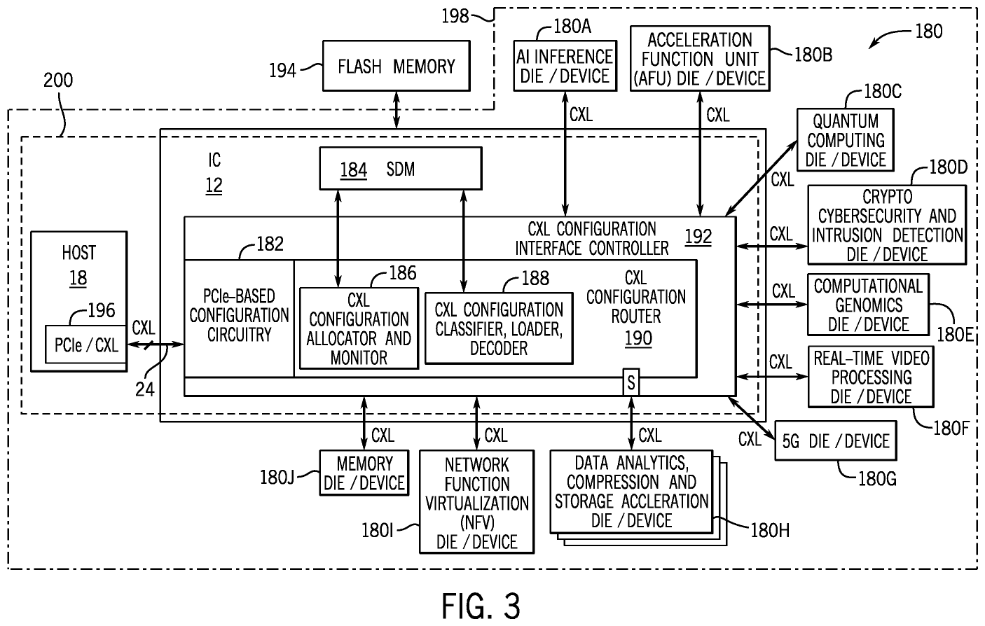

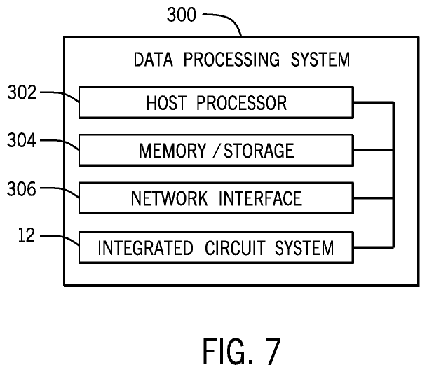

The integrated circuit 12 may be programmed to perform a wide variety of operations. One example shown in FIG. 3 is a disaggregated system that includes one or more dies (or devices) coupled to the integrated circuit 12. The system illustrated in FIG. 3 (e.g., the integrated circuit 12 as a field programmable gate array or programmable logic device (PLD) coupled to dies) may correspond to a disaggregated system architecture. Disaggregated systems may beneficially operate based on reprogrammable circuitry. For example, performing computations based on the integrated circuit 12 in a disaggregated system may enable lower cost and relatively fast prototyping relative to systems that used non-reprogrammable components. One example system that may use a disaggregated system is a computational genomics system (e.g., disaggregated die 180E) that accelerates genomic data analysis, which may operate based on relatively large datasets that improve computational analysis from re-programmability. Additional examples of disaggregated system applications are included herein, such as after discussion of FIG. 7.

To elaborate, FIG. 3 is a block diagram of the integrated circuit 12 (e.g., programmable logic device, field programmable gate array (FPGA)) that may include circuitry that enables the electronic device 13 and/or the host 18 to program one or more disaggregated dies 180 (disaggregated die 180A, disaggregated die 180B, disaggregated die 180C, disaggregated die 180D, disaggregated die 180E, disaggregated die 180F, disaggregated die 180G, disaggregated die 180H, disaggregated die 180I, disaggregated die 180J) in parallel with the integrated circuit 12. The one or more disaggregated dies 180 may be devices, sub-systems, chiplets, or any combination thereof. The one or more disaggregated dies 180 may have separate boards and/or separate packaging relative to each other and the integrated circuit 12.

The integrated circuit 12 may include a first protocol configuration circuitry (e.g., PCIe-based configuration circuitry 182), a secure device manager (SDM) 184, a second protocol configuration allocator and monitor (e.g., a Compute Express Link (CXL) configuration allocator and monitor 186), a second protocol configuration classifier, loader, decoder (e.g., a CXL configuration classifier, loader, decoder 188), a second protocol configuration router (e.g., a CXL configuration router 190), a second protocol configuration router (e.g., a CXL configuration interface controller 192), or the like. The integrated circuit 12 may communicatively couple to the one or more disaggregated dies 180, flash memory 194, or the like. The host 18 may communicatively couple to the integrated circuit 12 via a PCIe/CXL interface 196.

The integrated circuit 12 may communicate with the host 18 via a link 24 between the PCIe-based configuration circuitry 182 and the PCIe/CXL interface 196. The link 24 may include one or more layers of one or more different protocol stacks. The upper layers of the link 24 may be disposed on lower layers of the link 24. The upper layers may correspond to a transaction layer and a link layer. Each combination of a transaction layer and a link layer may enable data to be communicated between the PCIe-based configuration circuitry 182 and the PCIe/CXL interface 196. Some transaction and link layer pairings may be used to communicate PCIe and CXL traffic and some transaction and link layer pairings may be used to communicate CXL traffic. Other combinations of transaction and link layers may be included in the link 24 to expand operations to additional or alternative protocols than PCIe or CXL.

When considering a combined CXL and PCIe protocol system, traffic flows of different communication protocols may be sent along CXL interconnects. For example, traffic flows may include cache traffic flows (CXL.cache), input/output data traffic flows (CXL.io), memory traffic flows CXL.mem), or the like. One or more traffic flows may correspond to different communication protocols, enabling the various traffic flows to share CXL interconnects. The CXL interconnect may support various interconnect protocols, such as a non-coherent interconnect protocol, a coherent interconnect protocol, a memory interconnect protocol, and the link. Other examples of supported interconnect protocols may include PCI, PCIe, Universal Serial Bus (USB), in-die interconnect (IDI), On-chip System Fabric (IOSF) related protocols, system management interrupts (SMI) related protocols, Serial AT Attachment (SATA), CXL.io, CXL.cache, and CXL.mem, or the like, which each may convert to a CXL interface

A CXL link correspond to relatively low-latency and/or relatively high-bandwidth data communications. The CXL link may be implemented via discrete and/or on-package link, which may support a dynamic protocol multiplexing of coherency, memory access, and/or input/output (I/O) protocols. This set of protocols may include or be based on I/O semantics similar to PCIe (e.g., CXL.io), caching protocol semantics (e.g., CXL.cache), and memory access semantics (e.g., CXL.mem) over a discrete or on-package link. Multiplexing circuitry may enable multiplexing of CXL protocols, thereby enabling data of any one of the supported protocols to be sent, in a multiplexed manner, via a respective CXL link. may CXL may be a dynamic multi-protocol technology designed to support a vast spectrum of accelerators and/or system operations. As one example, a CXL link may enable an accelerator (e.g., disaggregated die 180B) to access system memory (e.g., flash memory 194, disaggregated die 180J) as a caching agent and/or host system memory. Indeed, the CXL links of FIG. 3 may enable intercommunication of any of the disaggregated die 180 the integrated circuit 12, the sub-systems of the integrated circuit 12 (e.g., SDM 184, CXL configuration router 190, and so on), flash memory 194, and so on. Based on the disaggregated system, all of the CXL protocols or only a subset of the protocols may be enabled. CXL may be built upon the PCIe infrastructure (e.g., PCIe 5.0), which may permit CXL communications to be made based on the PCIe physical and electrical interface. Using CXL communications on PCIe infrastructure may enable advanced interfacing and/or communication management in some operations, such as I/O, memory protocol (e.g., allowing a host processor to share memory with an accelerator device), coherency interface, or the like. Although systems and methods described herein focus on the example case of combined PCIe and CXL interconnections, it should be noted that other suitable combinations of protocols may be used to enable parallel configuration of integrated circuit 12 and one or more of the disaggregated dies 180.

Grouping 198 may correspond to the circuitry that communicates with the host 18 and/or the integrated circuit 12 at least based on CXL interconnect communications (e.g., pathways labelled “CXL” in FIG. 3). The grouping 198 may include disaggregated dies 180, the host 18, and the PCIe/CXL interface 196 while excluding at least the flash memory 194. Grouping 200 may correspond to the circuitry that communicates with the host 18 and/or the integrated circuit 12 at least based on PCIe bus communications. The grouping 200 may include the host 18, the PCIe/CXL interface 196, the SDM 184, the PCIe-based configuration circuitry 182, the CXL configuration allocator and monitor 186, the CXL configuration classifier, loader, decoder 188, the CXL configuration router 190, and the CXL configuration interface controller 192. Some circuitry of the grouping 200 may communicate using PCIe bus communications and/or CXL interconnect communications and thus may be considered dual communication-enabled circuitry. This dual communication-enabled circuitry may include the PCIe/CXL interface 196 and CXL configuration interface controller 192, which may operate to process PCIe communications into a format compatible with CXL communications or vice versa. In some cases, CXL communications are transmitted in a layer or multiplexed channel separate from the PCIe communications and/or according to another suitable data separation method.

The host 18 may program the integrated circuit 12 to prepare the integrated circuit 12 to perform one or more operations, and these various configuration operations described above are relied upon herein. The host 18 may transmit configuration data to the integrated circuit via the PCIe/CXL interface 196.

The PCIe-based configuration circuitry 182 may receive the configuration data from the host 18. Based on the configuration data, the PCIe-based configuration circuitry 182 may generate separate images for periphery and core logic of the integrated circuit 12. For example, an initialization mode may enable configuration of both periphery and programmable logic fabric (e.g., programmable logic blocks 110) of the integrated circuit 12, while an update mode may enable configuration of the programmable logic fabric directly by the host 18. The PCIe-based configuration circuitry 182 may perform protocol conversion operations, link management operations, data transfer operations, or the like between the host 18 and the integrated circuit 12. These operations may include one or more processing operations to change data sent using a first protocol on a PCIe bus (or a first layer of the PCIe bus) to a second protocol compatible with transmission on CXL interconnect (or a second layer of the PCIe bus dedicated to another protocol like CXL interconnect), or vice versa. Data moving circuitry may support movement of data between one or more of the disaggregated dies 180. Data moving circuitry of the PCIe-based configuration circuitry 182 may handle the movement of data from a memory of the host 18 to a memory of the integrated circuit (e.g., disaggregated die 180J, flash memory 194). The data moving circuitry may perform an address translation to maps one or more memory addresses requested by a CXL host to an appropriate address for the targeted disaggregated die(s) 180. PCIe-based configuration circuitry 182 may also include a command queue and/or response queue. The command queue and/or the response queue may store one or more incoming commands from the host 18. The command and response queue may sometimes store outgoing responses from the integrated circuit 12 sent to the disaggregated dies 180. For example, the command queue may receive requests from the host 18, while the response queue may hold the completed responses from the integrated circuit 12 before the completed response are sent back to host 18.

The SDM 184 may manage the configuration and/or initialization of the disaggregated dies 180 to enable CXL-based communications and/or other computing functionality. The SDM 184 may generate a configuration bitstream based on identified tasks and/or information received from the host 18.

The CXL configuration allocator and monitor 186 may manage and allocate system computing resources among the various sub-systems of the integrated circuit 12. The CXL configuration allocator and monitor 186 may coordinate computing resources among systems like the flash memory 194 and the SDM 184 to help appropriately divide the computing resources among the configuration process and the disaggregated dies 180. The monitor of the CXL configuration allocator and monitor 186 may observe and track the configuration behavior, performance, and/or specific error event handling. To do so, the CXL configuration allocator and monitor 186 may monitor the ongoing progress of a respective configuration process and one or more related statuses, such as statuses of the integrated circuit 12, one or more disaggregated dies 180, or the like.

The CXL configuration classifier, loader, decoder 188 may include classifier circuitry. The classifier circuitry may perform tasks, such as data classification, to identify or categorize different types of configuration data based on a format of one or more disaggregated dies 180. The classifier circuitry may handle different configurations based on specific criteria to distinguish between various configuration bitstreams. The CXL configuration classifier, loader, decoder 188 may include loading circuitry that loads data into a targeted disaggregated die 180. The loading circuitry may be used to transfer the configuration data from the integrated circuit 12 to one or more targeted disaggregated dies 180. The CXL configuration classifier, loader, decoder 188 may include decoding circuitry. The decoding circuitry may decode encoded data (e.g., encrypted data) based on an indication of desired or target security protocols to implement. The decoding circuitry may be used in encoded, encrypted, or compressed data flows. The decoding circuitry may process the data flows (e.g., encode, encrypt, compress) based on a format requirement of the respective disaggregated die 180 receiving the data flow. The decoding circuitry may decode data before the data is loaded into the integrated circuit 12 or transmitted to a respective disaggregated die 180. With this in mind, a first type of disaggregated die 180 may correspond to a first configuration and a first data flow (e.g., encode and compress operation) and a second type of disaggregated die 180 may correspond to a second configuration and a second data flow (e.g., encode and compress operation), where the first configuration and the second configuration may be different, where the first data flow and the second data flow are at least partially difference, and where the first type and the second type may be different. An indication of the criteria associating the first configuration and/or the first data flow to the first type of disaggregated die 180 and/or the second configuration and/or the second data flow to the second type of disaggregated die 180 may be stored in the flash memory 194 and/or the disaggregated die 180J.

The CXL configuration router 190 may handle the transfer of a configuration bitstream (e.g., configuration data) from the host 18 to the integrated circuit 12. The transfer of the configuration bitstream may occur via one or more switches and/or interconnecting circuitry associated with the disaggregated dies 180. Other than these sub-components, the CXL configuration router 190 may distribute and may connect each of the disaggregated dies 180 to route the configuration bitstream to the correct destination among the disaggregated dies 180. This distribution and coupling may be based on the indication of the criteria discussed above to aid with decoding and configuration selection operations. Indeed, memory (e.g., memory 194, memory disaggregated die 180J) may store one or more indications of criteria associating a switching or routing pattern to each of the disaggregated dies 180.

The CXL configuration interface controller 192 may manage the CXL interconnects between the integrated circuit 12 and one or more of the disaggregated dies 180. The management operations may include initializing one or more CXL interconnects when the integrated circuit 12 is powered on and/or initializing one or more of the disaggregated dies 180 by sending one or more control signals and programming data via a respective CXL interconnect, where the control signals may implement the programming data and/or where the programming data is directly loaded into configuration memories or registers of the disaggregated dies 180. The management operations may include discovery operations and/or enumeration operations. The discovery operations and/or enumeration operations may enable the integrated circuit 12 to provide a count to the host 18 of a number and type of the disaggregated dies coupled to the integrated circuit 12. The CXL configuration interface controller 192 may load a configuration bitstream selected by the CXL configuration classifier, loader, decoder 188 to the corresponding disaggregated die 180.

The flash memory 194 may store the integrated circuit 12 bitstream used to program programmable logic blocks 110 of the integrated circuit 12. By storing the bitstream in the flash memory 194, remote system updating may occur, such as by an external device with access to the flash memory 194 or the host 18 via communication with the integrated circuit 12. Furthermore, the flash memory 194 storing the bit stream may enable the flash memory 194 storage space to expand to store the bitstreams of the disaggregated dies 180 coupled to the integrated circuit 12 and being configuration via CXL if those configurations bitstreams are not directly originated from the host 18. Indeed, flash memory 194 may not be constrained in footprint of memory storage and thus may be expanded to suit the application (e.g., the number of disaggregated dies 180 being used in the disaggregated system).

The CXL configuration allocator and monitor 186, the CXL configuration classifier, loader, decoder 188, the CXL configuration router 190, and the CXL configuration interface controller 192 may be implemented in hard logic (e.g., not reprogrammable logic) of the integrated circuit 12. By implementing in hard logic, these sub-systems may not be reconfigured at startup by the host 18 like soft logic components are, which may help reduce overall boot times and computational cycles to configure each of the systems of the integrated circuit.

In some cases, the disaggregate dies 180 may couple to one CXL link of the integrated circuit 12 (e.g., 1:1) or may couple multiple disaggregated dies 180 to one CXL link (e.g., N:1) via switching circuitry. An example of N:1 coupling are illustrated in FIG. 3 relative to disaggregated dies 180H coupled to the integrated circuit 12 at switch “S,” which may be implemented in one or more programmable logic blocks 110 as soft logic (to be flexibly included in the integrated circuit 12 when indicated via a GUI associated with design software 14) and/or as hard logic (to be assigned via the GUI to a set, maximum number of disaggregated dies 180 corresponding to a number of switches available). It is noted that when using the switching circuitry, the integrated circuit 12 may generate one or more control signals to operate the switching circuitry into a desired state to couple the target disaggregated die 180 to the integrated circuit 12.

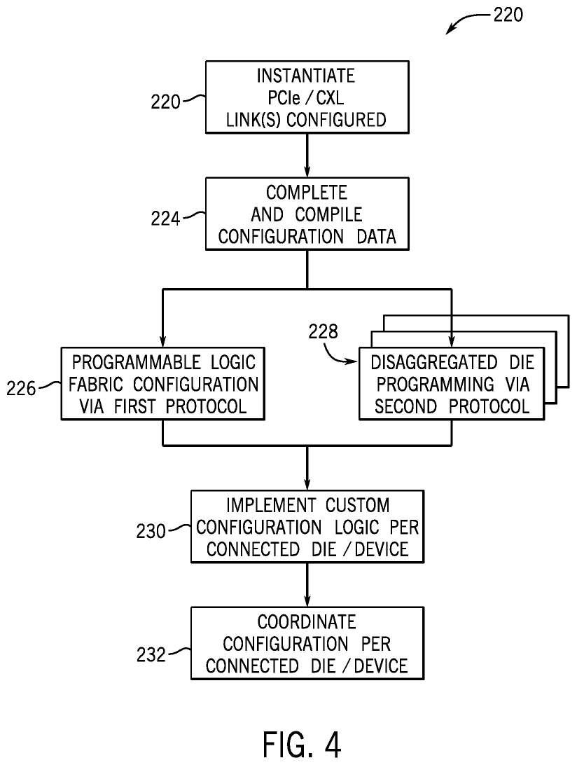

To elaborate on configuration methods, FIG. 4 is a diagrammatic representation of a method 220 performed via the host 18 and/or via the integrated circuit 12 to program the integrated circuit 12 in parallel with the disaggregated dies 180. Any suitable device may perform these operations described herein, such as processing circuitry of the host 18, processing circuitry of the integrated circuit 12, processing circuitry of the electronic device 13, or the like. In some systems, the method 220 may be implemented by executing instructions stored in a tangible, non-transitory, computer-readable medium using a processor (e.g., corresponding processor and corresponding memory of the host 18 and/or the integrated circuit 12). For example, the method 220 may be performed at least in part by one or more software components, such as an operating system of the host 18 and/or electronic device 13, one or more software applications of the host 18 and/or electronic device 13, and the like. While the method 220 is described using operations in an illustrated sequence, it should be understood that the present disclosure contemplates that some of the operations may be performed in a different sequence than the sequence illustrated, and that some operations may be skipped or not performed altogether.

Operations of the method 220 may be at least partially facilitated by a software or electronic design assistive program, such as the design software 14, which may enable programming or design of one or more application-specific resources manageable by the host 18. FIG. 4 illustrates, generally, that simultaneous or parallel programming for disaggregated devices 180 may be performed the integrated circuit 12 is being programmed. It is noted that the configuration of the programmable logic fabric of the integrated circuit 12 may take longer than the configuration of the disaggregated devices 180 since the programmable logic blocks 110 may operate based on far more bit settings and/or programmed components relative to the disaggregated devices 180, which may include one or more ASICs, one or more application-specific standard products specific to a type of application (ASSP), or other suitable circuitry that may operate based on a package design, a software loaded into memory, or the like during manufacturing and/or before being coupled to the integrated circuit 12. Although some user-defined configuration may be instantiated or programmed into the disaggregated devices 180, some resources of the disaggregated devices 180 may not be re-programmed after each power cycle (e.g., after being turned off then turned on again), which may differ from circuitry implemented in the programmable logic blocks 110 of the integrated circuit 12 (e.g., programmable logic fabric is reconfigured at power on of the integrated circuit 12).

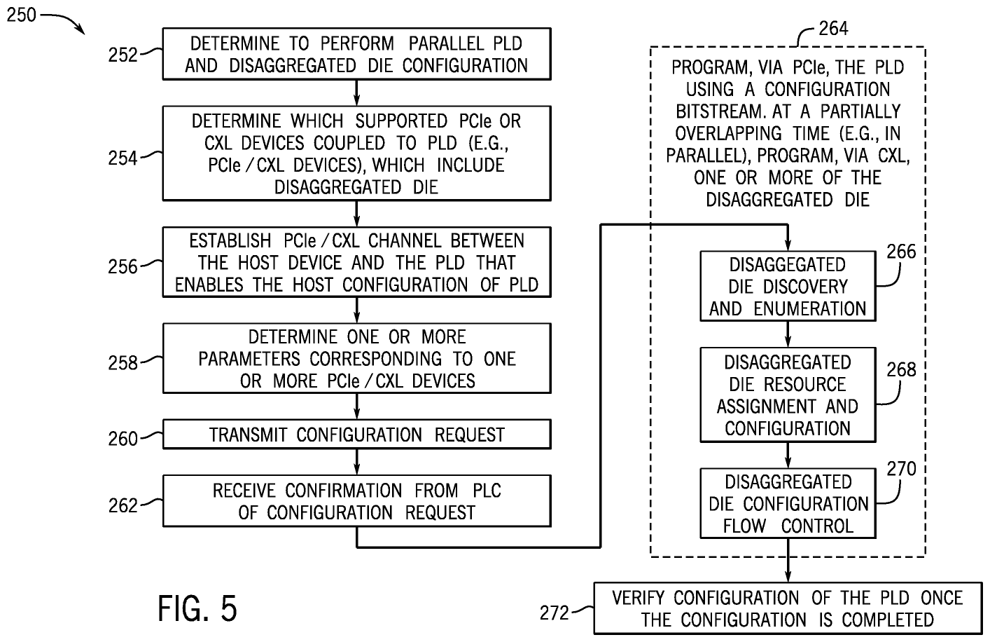

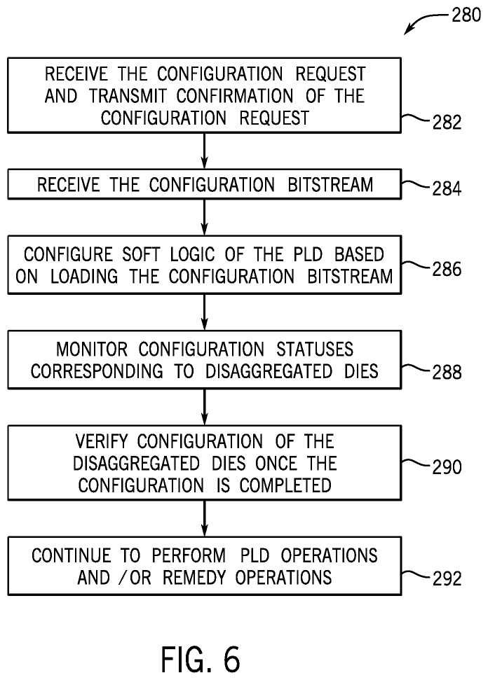

When power is supplied to the integrated circuit 12 and the host 18, the method 220 may be generally performed. Details of specific operations illustrated via FIG. 4 and the method 220 are elaborated further on in FIGS. 5-6 with reference to integrated circuit 12 operations and the host 18 operations. For ease of overview, the operations of the integrated circuit 12 and the host 18 are discussed together in FIG. 4 with reference to circuitry of FIGS. 1-3 and thus these earlier descriptions are relied upon herein.

After a power supply is coupled to the integrated circuit 12 and/or the host 18, the disaggregated dies 180 may commence bifurcation and/or enumeration operations. Once completed, the respective disaggregated dies 180 advertise their presence to the host 18. The respective disaggregated dies 180 may do by generating one or more control signals and/or data packets indicative of a respective identity and/or purpose of that respective disaggregated die 180. Based on the indication of presence advertised to the host 18, the host 18, at block 222, may instantiate PCIe/CXL links to the integrated circuit 12 and/or the disaggregated dies 180. Instantiating the PCIe/CXL links may involve load one or more image files to one or more of the disaggregated dies 180. The host 18 may generate one or more control signals that operate the PCIe/CXL links and/or intercoupled circuitry to load the one or more image files to various of the disaggregated dies 180. An image file may be a program file that includes instructions, data, and/or settings specific to one or more operations to be performed by a respective disaggregated die 180, such as in conjunction with operations of the programmable logic fabric of the integrated circuit 12. Image files may be managed in a central computing system and may be accessible via a cloud-accessible database and/or via periodic download by the electronic device 13. In this way, a centrally-managed catalog system may store and make available the various image files to be accessed by the electronic device 13 and deployed to the various disaggregated dies 180. The catalog system may correspond to an external computing system (e.g., cloud commuting system) disposed separately from the electronic device 13, the host 18, and/or the integrated circuit 12 and be accessed via wireless or wired connections. The host 18 may load one image file per disaggregated die 180, such as after reading the image file or obtaining the image file from the catalog system. In some cases, each disaggregated die 180 receives a different image file customized to its particular application or purpose within the disaggregated system. In some cases, the electronic device 13 receives a centrally-managed version of an image file be updated with user-specific parameters (e.g., via design software 14 operations) to help customize the image file loaded in the disaggregated system to a desired use. As such, the host 18 loads an image file corresponding for that disaggregated die 180 which was indicated via the advertisements. In some cases, these image files are transmitted based on pre-defined channels. In some cases, the electronic device 13, based on operations of the design software 14, may generate some or all of a respective image file.

Indeed, at block 224, the electronic device 13, via a graphical user interface presented based on instructions and/or code corresponding to providing the design software 14, may receive inputs and update a configuration file to be loaded into integrated circuit 12 to configure the programmable logic blocks 110 to implement one or more circuits. The circuits may correspond to circuitry to be implemented via the programmable logic blocks 110 (e.g., IP Modules). In some cases, the electronic device 13 may generate configuration bitstream that enables programmable logic fabric operations to be integrated with operations performed by the disaggregated dies 180. The integrated circuit 12 may implement customized logic via the configuration bitstream to handle respective data from each connected disaggregated die 180. This logic can include protocol translation, command interpretation, and/or register settings to be used when communicating with and/or processing data associated with respective disaggregated dies 180. The electronic device 13 providing the design software 14 may compile these inputs and other indications stored in memory associated with the design of the programmable logic blocks 110 of the integrated circuit 12 to generate a configuration bitstream.

At block 226, the host 18 begins configuration of one or more programmable logic blocks 110 based on a first protocol, such as the PCIe protocol, to implement a configuration bitstream generated via design software 14 and the electronic device 13. The host 18 may use one or more control signals to load the programmable logic blocks 110 with a configuration bitstream or other related data. At block 228, the host 18 begins programming one or more (e.g., each) of the disaggregated dies 180 based on a second protocol, such as the CXL protocol, to implement an image file on that respective disaggregated die 180. The electronic device 13 may provide data and instruct the host 18 to program the disaggregated dies 180 in parallel to integrated circuit 12 configuration. Diagrammatically, this is represented by a single block 226 being illustrated parallel to multiple blocks 228, representing one or more programming operations for one or more disaggregated dies 180. Programming one or more disaggregated dies 180 in parallel with the programmable logic configuration. Indeed, the parallel processing capabilities of the host 18 may further expand to parallel programming operations on multiple devices (e.g., disaggregated dies 180, other devices) connected via CXL interfaces. Thus, the integrated circuit 12 may initiate and execute configuration operations on multiple devices in parallel. As a result, the configuration time for the disaggregated system may significantly reduce when using parallel configuration operations relative to total time spent in sequential configuration operations. In addition, if each programming of the disaggregated dies 180 is performed based on CXL interfaces, no sideband interface may be used when programming the disaggregated dies 180. Indeed, the host 18 may program the disaggregated dies 180 based on inline programming via CXL interfaces and doing so may conserve pins of the integrated circuit 12 for managing other sideband interfaces and/or for other uses.

At block 230, the various configuration and programming operations of blocks 226 and 228 may implement custom configuration logic on the integrated circuit 12 and on the one or more disaggregated dies 180 (e.g., each die programmed via block 228). After implementation, circuitry implemented in the programmable logic blocks 110 of the integrated circuit 12 may communicate with one or more disaggregated dies 180 to perform processing operations. Based on the information loaded via the configuration bitstream, the integrated circuit 12, via circuitry implemented in the programmable logic blocks 110, may translate between protocols used by the integrated circuit 12 and one or more disaggregated dies 180, interpret commands sent from one or more disaggregated dies 180, translate commends to be sent to one or more disaggregated dies 180, read register settings to handle data to or from one or more disaggregated dies 180, and the like.

In some systems, at block 232, the integrated circuit 12 may, via CXL configuration interface controller 192, may synchronize programming operations of the disaggregated dies 180 based on timing requirements and provided statuses from the disaggregated dies 180 and/or other connected devices. By doing so, the integrated circuit 12 may enable timely and non-conflicting configuration operations for each connected device (e.g., disaggregated dies 180, other connected devices). For example, the integrated circuit 12 may coordinate programming operations, manage timing constraints, and ensure that conflicts or timing issues do not occur. The integrated circuit 12 may act as a central controller that orchestrates the processing operations to smooth execution and balance resources, which may help avoid processing bottlenecks or other resource consumption inefficiencies.

Referring back to operations associated with block 224, the design software 14 may cause the electronic device 13 to present a graphical user interface (GUI). The electronic device 13 may, via the GUI, receive inputs and/or instructions related to generating the configuration bitstream and/or customizing operations. The GUI may enable inputs to be received that correspond to an indication of a number of CXL channels available for the host 18 and the disaggregated dies 180. It is noted the integrated circuit 12 may report the indication of the number of CXL channels to the electronic device 13 when reporting the disaggregated dies 180 at block 222. In one example GUI, the GUI may include an input field that presents a closed list of indications of possible class and part numbers identifiers corresponding to the integrated circuit 12. The GUI may include an input field or a button visualization that enables one or more indications of a CXL channel(s) to be added to the GUI. When the electronic device 13 receives an input corresponding to the button visualization being selected, the electronic device 13 may update a presentation of the GUI to add an indication of CXL channel. The GUI may include additional visualizations that communicate options by which the CXL channel may be edited. The CXL channel that was added and any edits made to the visualization on the GUI via inputs to the GUI may change information included in the configuration bitstream by the electronic device 13. In some cases, the electronic device 13 may compare specifications of the class and part number indicated to the number or edits to the visualization of the CXL channel to “fact check” the edit and/or confirm that the edit is physically able to be incorporated by the integrated circuit 12 at configuration.

After a CXL channel is added via the GUI, the electronic device 13 may update the GUI to depict a selection box overlaid on at least a portion of the GUI (e.g., selection box “pop up”). The selection box may provide an input field to receive an input (e.g., alphanumeric input, selection from a drop-down list) regarding a type and a purpose of a device coupled via that added CXL channel. For example, if the device intended to be coupled via the added CXL channel is a disaggregate die 180, the type of the die may correspond to model number of its ASIC/ASSP die and the purpose of the device may be an indication of its operation (e.g., “network function virtualization (NFV) die” or other suitable operand description of FIG. 3). The selection box may also provide an input field to receive data related to how that device (e.g., disaggregate die 180) is to be coupled to the CXL channel, such as whether that device is coupled 1:1 to the integrated circuit 12 and/or N:1 through a switching circuitry (e.g., multiple devices coupled to one CXL link to the integrated circuit 12). The selection box may provide an input field to receive an input indicating whether the disaggregated die 180 is going to be programmed by the host 18 or via flash memory 194 disposed outside the integrated circuit 12. This indication may change how the configuration bitstream and/or image file is loaded into the host 18 and/or prepared for programming into the flash memory 194. Any suitable number of CXL channels may be added via the GUI to enable the GUI visualizations to match the hardware of the disaggregated system being programmed. Doing so may enable the electronic device 13, via the design software 14, to have accurate and up-to-date information regarding used and unused portions of the integrated circuit 12 for compilation and finalization of the configuration bitstream.

FIG. 5 is a flowchart of a method 250 performed by the host 18 to individually program the disaggregated dies 180 in parallel to configuration of the integrated circuit device 12. Other suitable devices may sometimes perform some or all of these operations described herein, such as processing circuitry of the host 18, processing circuitry of the integrated circuit 12, processing circuitry of the electronic device 13, or the like. In some systems, the method 250 may be implemented by executing instructions stored in a tangible, non-transitory, computer-readable medium using a processor (e.g., corresponding processor and corresponding memory of the host 18 and/or the integrated circuit 12). For example, the method 250 may be performed at least in part by one or more software components, such as an operating system of the host 18 and/or electronic device 13, one or more software applications of the host 18 and/or electronic device 13, and the like. While the method 250 is described using operations in an illustrated sequence, it should be understood that the present disclosure contemplates that some of the operations may be performed in a different sequence than the sequence illustrated, and that some operations may be skipped or not performed altogether.

At block 252, the host 18 may determine to configure the integrated circuit 12 (e.g., PLD) and program the disaggregated dies 18 in parallel. At block 254, the host 18 may determine one or more PCIe or CXL devices coupled to PLD (e.g., PCIe/CXL devices), which include the disaggregated die 180.

At block 256, the host 18 may establish the link 24 between the host 18 and the integrated circuit 12. The link 24 that enables the host 18 configuration of the programmable logic blocks 110 of the integrated circuit 12. The link 24 may be a PCIe/CXL channel able to communicate using the PCIe protocol and the CXL protocol.

At block 258, the host 18 may determine one or more parameters corresponding to the one or more PCIe/CXL devices identified at block 254. The parameters may identify respective device types, capabilities, and data handling methods to use when programming the one or more PCIe/CXL devices identified at block 254. The host 18 may determine the one or more parameters by reading indications stored in a memory, by receiving the parameters from the PCIe/CXL devices via link 24, or the like.

At block 260, the host 18 may transmit a configuration request to the integrated circuit 12. At block 262, the host 18 may receive a confirmation from the integrated circuit 12 of approval of the configuration request.

In response to the confirmation, at block 264, the host 18 may program, via PCIe, the PLD using a configuration bitstream and may, at an at least partially overlapping time frame (e.g., in parallel), program, via CXL, one or more of the disaggregated dies 180. To do so, the host 18 may perform operations of blocks 266, 268, and 270.

Indeed, at block 266, the host 18 may perform disaggregated die 180 discovery and enumeration operations by the host 18 initiating a discovery process to identify and enumerate disaggregated dies 180 coupled to the integrated circuit 12. Discovering and enumerating the disaggregated dies 180 may enable the host 18 to provide image files to program the disaggregated dies 180 based on respective identities of the dies, as well as track which of the disaggregated dies 180 has been programmed.

At block 268, the host 18 may perform disaggregated die 180 resource assignment and programming operations. Programming of the disaggregated die 180 may occur based on image files generated by the electronic device 13, as described above with reference to method 220. The discovered and enumerated disaggregated dies 180 from block 266 may be matched to corresponding image files by the host 18 based on a purpose or identify of the disaggregated dies 180. The host 18 may program the disaggregated dies 180 with its corresponding image file. The number of disaggregated dies 180 determined at block 266 may be used by the host 18 to track and coordinate these programming operations, such as to identify when a last die has been programmed.

At block 270, the host 18 may perform disaggregated die 180 programming flow control operations. Indeed, the host 18 may control programming settings of the disaggregated dies 180. The host 18 may make run-time adjustments to adapt usage models and optimize performance (e.g., correct performance to reduce lag or computational bottlenecking) if the host 18 determines an adjustment is to occur. The host 18 may adjust the programming flow control operations based on reports received over time from the CXL configuration interface controller 192.

At block 272, the host 18 may verify configuration of the disaggregated system based on the configuration of the integrated circuit 12 and the programming of the disaggregated dies 180. Verifying the configuration may involve the host 18 deploying a monitor system on the integrated circuit 12 to track the status and any issued error messages when an unexpected operation occurs. Once the process is finished, the host 18 verifies that the disaggregated system operates as desired based on any suitable verification method. One example verification method may involve applying test data to one or more portions of the disaggregated system and to the design software 14 (e.g., that generated the configuration bitstream) to confirm both resulting data matches and/or negligibly differs from each other.

In some systems, the host 18 may perform some of the operations of block 264 at an earlier time than after operations of block 262. For example, the host 18 may begin initiating programming operations via CXL links after identifying the supported CXL devices. Thus, the host 18 may not have to wait to program the disaggregated dies 180 until after operations of block 256 are performed to establish the PCIe/CXL channel between host 18 and integrated circuit 12. Indeed, the link 24 may more quickly establish the CXL channel for communications and/or the integrated circuit 12 may program the disaggregated dies 180 based on image files stored in the flash memory 194. The host 18 may allocate memory space for the configuration in anticipation of loading the image file from the flash memory 194 to the respective disaggregated die 180. To program one or more of the disaggregated dies 180 without the link 24 via the flash memory 194, a direct memory access (DMA) operation may be used to access the image files from the flash memory 194 without the link 24.

The integrated circuit 12 may perform operations to complement and support operations described in FIG. 5 of the host 18. To elaborate, FIG. 6 is a flowchart of a method 280 that may be performed by the integrated circuit 12 to program, via the CXL configuration interface controller 192, one or more disaggregated dies 180 in parallel with configuration of the integrated circuit device 12. Other suitable devices may sometimes perform some or all of these operations described herein, such as processing circuitry of the host 18, processing circuitry of the integrated circuit 12, processing circuitry of the electronic device 13, or the like. In some systems, the method 280 may be implemented by executing instructions stored in a tangible, non-transitory, computer-readable medium using a processor (e.g., corresponding processor and corresponding memory of the host 18 and/or the integrated circuit 12). For example, the method 280 may be performed at least in part by one or more software components, such as an operating system of the host 18 and/or electronic device 13, one or more software applications of the host 18 and/or electronic device 13, and the like. While the method 280 is described using operations in an illustrated sequence, it should be understood that the present disclosure contemplates that some of the operations may be performed in a different sequence than the sequence illustrated, and that some operations may be skipped or not performed altogether.

At block 282, the integrated circuit 12 may receive the configuration request from the host 18. In response to the configuration request, the integrated circuit 12 may transmit a confirmation of the configuration request. The confirmation may be used by the host 18 to trigger configuration and programming operations of FIG. 5 (e.g., operations of block 264), which may include transmitting a configuration bitstream to the integrated circuit 12. At block 284, the integrated circuit 12 may receive the configuration bitstream from the host 18 via the link 24 using the first protocol (e.g., PCIe). At block 286, the integrated circuit 12 may initiate configuration of its programmable logic circuitry (e.g., soft logic) based on the configuration bitstream. The integrated circuit 12 may load the configuration bitstream to the SDM 184.

At block 288, the integrated circuit 12 may monitor configuration statuses corresponding to disaggregated dies 180 via PCIe/CXL process. The integrated circuit 12 may do so based on the CXL configuration allocator and monitor 186 and/or another monitor system deployed by the host 18. The integrated circuit 12 may determine whether a configuration error arises based on the monitoring the configuration statuses. If an error arises, the integrated circuit 12 may perform an error event handling and recovery process. The error event handling and recovery process may include link retry and recovery operations, timer monitoring for the link retry, and/or capturing of the status and error message. Indeed, the error event handling and recovery process may enable the host 18 and/or the integrated circuit 12 to debug the configuration statuses related to the programmable logic blocks 110 configuration and/or the programming of the disaggregated dies 180.

At block 290, the integrated circuit 12 may verify operation of the disaggregated dies 180 after programming. The host 18 may verify operation (at block 272) of the disaggregated system based on verification results generated by the integrated circuit 12. Operations may be verified once a respective disaggregated die 180 is programmed, thus some verification operations of a set of disaggregated dies 180 may occur in parallel with some programming operations of a different set of the disaggregated dies 180. The integrated circuit 12 may receive expected output data and test data corresponding to the disaggregated die 180 under test from the host 18 and/or the flash memory 194. The expected output data may correspond to an expected output from the disaggregated dies 180 when one or more disaggregated dies 180 receive the test data. The integrated circuit 12 may transmit the test data to the one or more disaggregated dies 180, receive output data from the one or more disaggregated dies 180, and determine that the operation is validated when the output data matches (or negligibly differs) from the expected output data.

The integrated circuit 12 may receive an indication that the disaggregated system is validated from the host 18. In response to this indication, at block 292, the integrated circuit 12 may continue to perform processing operations based on the loaded configuration bitstream and/or perform remedy operations to correct programming of one or more disaggregated dies 180, if a configuration error was identified at blocks 288 or 290 in the one or more disaggregated dies 180.

It is noted that FIGS. 5-7 present one example of coordinated operations between host 18, the integrated circuit 12, and the disaggregated dies 180. It should be understood that other suitable configuration methods and/or coordinated operations may be performed herein to program the disaggregated dies 180 in parallel with configuration of the programmable logic blocks 110 of the integrated circuit 12.

With the foregoing in mind, the integrated circuit system 12 may be a component included in a data processing system, such as a data processing system 300, shown in FIG. 7. FIG. 7 is a block diagram of a data processing system that may incorporate the integrated circuit of FIG. 1 with a host processor.

The data processing system 300 may include the integrated circuit system 12 (e.g., a programmable logic device), a host processor 302, memory and/or storage circuitry 304, and a network interface 306. The data processing system 300 may include more or fewer components (e.g., electronic display, user interface structures, application specific integrated circuits (ASICs)). The host processor 302 may include any of the foregoing processors that may manage a data processing request for the data processing system 300 (e.g., to perform encryption, decryption, machine learning, video processing, voice recognition, image recognition, data compression, database search ranking, bioinformatics, network security pattern identification, spatial navigation, cryptocurrency operations, or the like). The memory and/or storage circuitry 304 may include random access memory (RAM), read-only memory (ROM), one or more hard drives, flash memory, or the like. The memory and/or storage circuitry 304 may hold data to be processed by the data processing system 300. In some cases, the memory and/or storage circuitry 304 may also store configuration programs (e.g., bitstreams, mapping function) for programming the integrated circuit system 12. The network interface 306 may allow the data processing system 300 to communicate with other electronic devices. The data processing system 300 may include several different packages or may be contained within a single package on a single package substrate. For example, components of the data processing system 300 may be located on several different packages at one location (e.g., a data center) or multiple locations. For instance, components of the data processing system 300 may be located in separate geographic locations or areas, such as cities, states, or countries.

The data processing system 300 may be part of a data center that processes a variety of different requests. For instance, the data processing system 300 may receive a data processing request via the network interface 306 to perform encryption, decryption, machine learning, video processing, voice recognition, image recognition, data compression, database search ranking, bioinformatics, network security pattern identification, spatial navigation, digital signal processing, or other specialized tasks.

Indeed, specific examples of applications for the disaggregated system of FIG. 3 may include dies that include circuitry to perform operations, where a wide variety of operations may be performed via the dies. For example, the circuitry may be associated with disaggregated and heterogeneous computing environments (e.g., disaggregated die 180A) that may be adaptively programmed to perform operations, such as inference generation as part of neural network models to associate data outputs between disaggregated dies/devices of the integrated circuit 12 and/or other integrated circuits 12. These the circuitry may be associated with accelerator function units (AFU) (e.g., disaggregated die 180B) that enable hardware accelerators to perform one or more workloads, where the AFU and/or hardware accelerators may be reprogrammed between workloads or portions of workloads. The circuitry may be associated with memory circuitry (e.g., disaggregated die 180J) to perform or enable operations, such as sharing relatively high-speed memory, data pooling, and/or data coherency among devices or datasets. The circuitry may be associated with Network Function Virtualization (NFV) (e.g., disaggregated die 180I) of network functions, which may enable different packet processing, traffic shaping, and/or virtual switching to be performed between devices and/or datasets. The circuitry may be associated with data analytics, compression, and/or storage acceleration operations (e.g., disaggregated die 180H), which may be used in accelerating analytics, compression and/or storage algorithms, and/or other related memory or processing operations. The circuitry may be associated with operations that include quantum computing (e.g., disaggregated die 180C). The operations may include 5G (e.g., disaggregated die 180G) or other radio frequency supporting processing, such as baseband processing, beamforming, massive multiple-in, multiple-out (MIMO) data handling and/or network slicing, or other suitable front end data processing operations to prepare datasets for transmission over cellular networks or other wireless networks. The circuitry may be associated with real-time video processing circuitry (e.g., disaggregated die 180F), which may include adaptive configuration/reconfiguration to improve timing of encoding, decoding, and/or filtering processes. The circuitry may be associated with crypto, cybersecurity, and/or intrusion detection circuitry (e.g., (e.g., disaggregated die 180D) that enable enhanced security monitoring or response operations between host device (e.g., host 18) and the integrated circuit 12 (e.g., PLD, FPGA). Other applications that may use configuration via CXL methods described herein, and thus may correspond to circuitry disposed on a disaggregated die 180, include as autonomous vehicle data processing, high-frequency or automated robotic trading, virtual and/or augmented reality, healthcare, agriculture, medical and industrial automation, and so on.

Systems and methods described herein may relate to one or more dies and/or devices being communicatively coupled to a programmable logic device as part of a disaggregated system. By using the systems and methods described herein, the programmable logic device may be used as a protocol bridge between a host device and disaggregated dies. Using the programmable logic device as the protocol bridge enables programming of the one or more disaggregated dies in parallel with configuration of the programmable logic device. Parallel programming operations may reduce boot times, reduce usage of input/output pin counts (e.g., pins of FPGA), and/or reduce complexity associated with system-to-system communications and/or cross-system integrations.

While the embodiments set forth in the present disclosure may be susceptible to various modifications and alternative forms, specific embodiments have been shown by way of example in the drawings and have been described in detail herein. However, it should be understood that the disclosure is not intended to be limited to the particular forms disclosed. The disclosure is to cover all modifications, equivalents, and alternatives falling within the spirit and scope of the disclosure as defined by the following appended claims.

The techniques presented and claimed herein are referenced and applied to material objects and concrete examples of a practical nature that demonstrably improve the present technical field and, as such, are not abstract, intangible or purely theoretical. Further, if any claims appended to the end of this specification contain one or more elements designated as “means for [perform]ing [a function] . . . ” or “step for [perform]ing [a function] . . . ”, it is intended that such elements are to be interpreted under 35 U.S.C. 112 (f). However, for any claims containing elements designated in any other manner, it is intended that such elements are not to be interpreted under 35 U.S.C. 112 (f).

### EXAMPLE EMBODIMENTS

EXAMPLE EMBODIMENT 1. An integrated circuit comprising:
programmable logic circuitry configurable based on first configuration data received via a first bus using a first protocol; and
disaggregated die configuration circuitry disposed outside the programmable logic circuitry, wherein one or more disaggregated dies are configurable based on second configuration data received via the first bus using a second protocol, and wherein one or more disaggregated dies are configurable in parallel with the programmable logic circuitry based on the disaggregated die configuration circuitry.

EXAMPLE EMBODIMENT 2. The integrated circuit of example embodiment 1, wherein the first protocol corresponds to a Peripheral Component Interconnect Express (PCIe) bus.

EXAMPLE EMBODIMENT 3. The integrated circuit of example embodiment 1, wherein the second protocol corresponds to a Compute Express Link (CXL) bus.

EXAMPLE EMBODIMENT 4. The integrated circuit of example embodiment 1, wherein the disaggregated die configuration circuitry is implemented in hard logic of the integrated circuit.

EXAMPLE EMBODIMENT 5. The integrated circuit of example embodiment 1, wherein the disaggregated die configuration circuitry comprises a configuration interface controller configurable to manage programming of the one or more disaggregated dies.

EXAMPLE EMBODIMENT 6. The integrated circuit of example embodiment 1, comprising a secure device manager that configures the programmable logic circuitry based on the first configuration data, wherein the first configuration data comprises a configuration bitstream.

EXAMPLE EMBODIMENT 7. The integrated circuit of example embodiment 1, comprising a router configurable to:
receive the second configuration data from a host device;
determine a target disaggregated die based on the second configuration data; and
transmit the second configuration data to the target disaggregated die.

EXAMPLE EMBODIMENT 8. The integrated circuit of example embodiment 1, comprising a configuration interface controller corresponding to the second protocol, wherein the configuration interface controller is configurable to:
receive a configuration request from a host device;
receive a configuration bitstream from the host device;
configure the programmable logic circuitry based on loading the configuration bitstream to a secure device manager (SDM);
monitor configuration statuses corresponding to the one or more disaggregated dies, wherein the one or more disaggregated dies are configurable in parallel with each other and with the programmable logic circuitry;
verify a configuration of the one or more disaggregated dies; and
perform a processing operation based on the one or more disaggregated dies and the programmable logic circuitry.

EXAMPLE EMBODIMENT 9. A tangible, non-transitory, computer-readable medium comprising instructions that, when executed by a processor, cause an electronic device to perform operations comprising:
establishing a data channel with an integrated circuit, wherein the data channel comprises a first layer corresponding to a first protocol and a second layer corresponding to a second protocol;
programming, via the first layer of the data channel, programmable logic of the integrated circuit based on configuration data; and
   programming, via the second layer of the data channel, a die of a plurality of dies via the integrated circuit based on an image file, wherein programming the integrated circuit and programming the plurality of dies occur during an at least partially overlapping timeframe.

EXAMPLE EMBODIMENT 10. The tangible, non-transitory, computer-readable medium of example embodiment 9, wherein the instructions cause the electronic device to perform operations comprising:
receiving an indication of the plurality of dies communicatively coupled to an integrated circuit;
for each die of the plurality of dies:
identifying that a respective die is coupled to the integrated circuit;
determining a respective image file corresponding to that respective die based on identifying that the respective die is coupled to the integrated circuit; and
sending that respective image file to that respective die via the second layer of the data channel.

EXAMPLE EMBODIMENT 11. The tangible, non-transitory, computer-readable medium of example embodiment 9, wherein the instructions cause the electronic device to perform operations comprising:
identifying that the die corresponds to a real-time video processing die;
selecting, from a plurality of image files, that the image file corresponds to the die based on identifying the die as corresponding to the real-time video processing die; and
transmitting, via the second layer of the data channel, the image file to the die through the integrated circuit.

EXAMPLE EMBODIMENT 12. The tangible, non-transitory, computer-readable medium of example embodiment 11, wherein the instructions cause the electronic device to perform operations comprising:
identifying that the die corresponds to the real-time video processing die and an identifier; and
selecting, from the plurality of image files, that the image file corresponds to the die based on the identifier and identifying the die as corresponding to the real-time video processing die, wherein the image file comprises custom logic different from another image file corresponding to another real-time video processing die.

EXAMPLE EMBODIMENT 13. The tangible, non-transitory, computer-readable medium of example embodiment 9, wherein the first layer of the data channel corresponds to a Peripheral Component Interconnect Express (PCIe) protocol, and wherein the second layer of the data channel corresponds to a Compute Express Link (CXL) protocol.

EXAMPLE EMBODIMENT 14. The tangible, non-transitory, computer-readable medium of example embodiment 9, wherein the instructions cause the electronic device to perform operations comprising:
programming, via the second layer of the data channel, one or more die of the plurality of dies at least in part by:
receiving, via the second layer of the data channel, an indication of each die of the plurality of dies;
reading a plurality of image files respectively corresponding to each die of the plurality of dies based on the indication of each die of the plurality of dies; and
transmitting, via the second layer of the data channel, the plurality of image files to the plurality of dies, respectively.

EXAMPLE EMBODIMENT 15. A tangible, non-transitory, computer-readable medium comprising instructions that, when executed by a processor, cause a programmable logic device to perform operations comprising:
establishing a data channel with a host device, wherein the data channel comprises a first layer corresponding to a first protocol and a second layer corresponding to a second protocol;
receiving, via the first layer of the data channel, a configuration bitstream from the host device;
programming, via a secure device manager (SDM), programmable logic of the programmable logic device with the configuration bitstream;
receiving, via the second layer of the data channel, an image file from the host device; and
programming, via a configuration interface controller, a die of a plurality of dies with the image file, wherein the programmable logic and the plurality of dies are programmed at an at least partially overlapping time frame.

EXAMPLE EMBODIMENT 16. The tangible, non-transitory, computer-readable medium of example embodiment 15, wherein the first layer of the data channel corresponds to a Peripheral Component Interconnect Express (PCIe) protocol, and wherein the second layer of the data channel corresponds to a Compute Express Link (CXL) protocol.

EXAMPLE EMBODIMENT 17. The tangible, non-transitory, computer-readable medium of example embodiment 15, wherein the plurality of dies are external to the programmable logic device, and wherein each die of the plurality of dies is on a separate package.

EXAMPLE EMBODIMENT 18. The tangible, non-transitory, computer-readable medium of example embodiment 15, wherein the die corresponds to a chiplet.

EXAMPLE EMBODIMENT 19. The tangible, non-transitory, computer-readable medium of example embodiment 18, wherein the die corresponds to quantum computing circuitry, accelerator circuitry, cybersecurity or intrusion detection circuitry, real-time video processing circuitry, radio frequency signal processing circuitry, network function virtualization circuitry, or any combination thereof, and wherein the die is programmed with the image file different from each other image file used to program each other die of the plurality dies.

EXAMPLE EMBODIMENT 20. The tangible, non-transitory, computer-readable medium of example embodiment 15, wherein the instructions cause the programmable logic device to perform operations comprising:
receiving a plurality of image files respectively corresponding to the plurality of dies; and
routing, via a configuration router, a respective image file of the plurality of image files to a respective die of the plurality of dies based on an identifier of the respective die and an identifier of the respective image file, wherein the routing of the respective image file occurs via a pathway corresponding to the second protocol.

What is claimed is:

1. An integrated circuit comprising:
programmable logic circuitry configurable based on first configuration data received via a first bus using a first protocol; and
disaggregated die configuration circuitry disposed outside the programmable logic circuitry, wherein one or more disaggregated dies are configurable based on second configuration data received via the first bus using a second protocol, and wherein one or more disaggregated dies are configurable in parallel with the programmable logic circuitry based on the disaggregated die configuration circuitry.

2. The integrated circuit of claim 1, wherein the first protocol corresponds to a Peripheral Component Interconnect Express (PCIe) bus.

3. The integrated circuit of claim 1, wherein the second protocol corresponds to a Compute Express Link (CXL) bus.

4. The integrated circuit of claim 1, wherein the disaggregated die configuration circuitry is implemented in hard logic of the integrated circuit.

5. The integrated circuit of claim 1, wherein the disaggregated die configuration circuitry comprises a configuration interface controller configurable to manage programming of the one or more disaggregated dies.

6. The integrated circuit of claim 1, comprising a secure device manager that configures the programmable logic circuitry based on the first configuration data, wherein the first configuration data comprises a configuration bitstream.

7. The integrated circuit of claim 1, comprising a router configurable to:
receive the second configuration data from a host device;
determine a target disaggregated die based on the second configuration data; and
transmit the second configuration data to the target disaggregated die.

8. The integrated circuit of claim 1, comprising a configuration interface controller corresponding to the second protocol, wherein the configuration interface controller is configurable to:
receive a configuration request from a host device;
receive a configuration bitstream from the host device;
configure the programmable logic circuitry based on loading the configuration bitstream to a secure device manager (SDM);
monitor configuration statuses corresponding to the one or more disaggregated dies, wherein the one or more disaggregated dies are configurable in parallel with each other and with the programmable logic circuitry;
verify a configuration of the one or more disaggregated dies; and
perform a processing operation based on the one or more disaggregated dies and the programmable logic circuitry.

9. A tangible, non-transitory, computer-readable medium comprising instructions that, when executed by a processor, cause an electronic device to perform operations comprising:
establishing a data channel with an integrated circuit, wherein the data channel comprises a first layer corresponding to a first protocol and a second layer corresponding to a second protocol;
programming, via the first layer of the data channel, programmable logic of the integrated circuit based on configuration data; and
programming, via the second layer of the data channel, a die of a plurality of dies via the integrated circuit based on an image file, wherein programming the integrated circuit and programming the plurality of dies occur during an at least partially overlapping timeframe.

10. The tangible, non-transitory, computer-readable medium of claim 9, wherein the instructions cause the electronic device to perform operations comprising:
receiving an indication of the plurality of dies communicatively coupled to an integrated circuit;
for each die of the plurality of dies:
identifying that a respective die is coupled to the integrated circuit;
determining a respective image file corresponding to that respective die based on identifying that the respective die is coupled to the integrated circuit; and
sending that respective image file to that respective die via the second layer of the data channel.

11. The tangible, non-transitory, computer-readable medium of claim 9, wherein the instructions cause the electronic device to perform operations comprising:
identifying that the die corresponds to a real-time video processing die;
selecting, from a plurality of image files, that the image file corresponds to the die based on identifying the die as corresponding to the real-time video processing die; and
transmitting, via the second layer of the data channel, the image file to the die through the integrated circuit.

12. The tangible, non-transitory, computer-readable medium of claim 11, wherein the instructions cause the electronic device to perform operations comprising:
identifying that the die corresponds to the real-time video processing die and an identifier; and
selecting, from the plurality of image files, that the image file corresponds to the die based on the identifier and identifying the die as corresponding to the real-time video processing die, wherein the image file comprises custom logic different from another image file corresponding to another real-time video processing die.

13. The tangible, non-transitory, computer-readable medium of claim 9, wherein the first layer of the data channel corresponds to a Peripheral Component Interconnect Express (PCIe) protocol, and wherein the second layer of the data channel corresponds to a Compute Express Link (CXL) protocol.

14. The tangible, non-transitory, computer-readable medium of claim 9, wherein the instructions cause the electronic device to perform operations comprising:
programming, via the second layer of the data channel, one or more die of the plurality of dies at least in part by:
receiving, via the second layer of the data channel, an indication of each die of the plurality of dies;
reading a plurality of image files respectively corresponding to each die of the plurality of dies based on the indication of each die of the plurality of dies; and
transmitting, via the second layer of the data channel, the plurality of image files to the plurality of dies, respectively.

15. A tangible, non-transitory, computer-readable medium comprising instructions that, when executed by a processor, cause a programmable logic device to perform operations comprising:
establishing a data channel with a host device, wherein the data channel comprises a first layer corresponding to a first protocol and a second layer corresponding to a second protocol;
receiving, via the first layer of the data channel, a configuration bitstream from the host device;
programming, via a secure device manager (SDM), programmable logic of the programmable logic device with the configuration bitstream;
receiving, via the second layer of the data channel, an image file from the host device; and
programming, via a configuration interface controller, a die of a plurality of dies with the image file, wherein the programmable logic and the plurality of dies are programmed at an at least partially overlapping time frame.

16. The tangible, non-transitory, computer-readable medium of claim 15, wherein the first layer of the data channel corresponds to a Peripheral Component Interconnect Express (PCIe) protocol, and wherein the second layer of the data channel corresponds to a Compute Express Link (CXL) protocol.

17. The tangible, non-transitory, computer-readable medium of claim 15, wherein the plurality of dies are external to the programmable logic device, and wherein each die of the plurality of dies is on a separate package.

18. The tangible, non-transitory, computer-readable medium of claim 15, wherein the die corresponds to a chiplet.

19. The tangible, non-transitory, computer-readable medium of claim 18, wherein the die corresponds to quantum computing circuitry, accelerator circuitry, cybersecurity or intrusion detection circuitry, real-time video processing circuitry, radio frequency signal processing circuitry, network function virtualization circuitry, or any combination thereof, and wherein the die is programmed with the image file different from each other image file used to program each other die of the plurality dies.

20. The tangible, non-transitory, computer-readable medium of claim 15, wherein the instructions cause the programmable logic device to perform operations comprising:
receiving a plurality of image files respectively corresponding to the plurality of dies; and
routing, via a configuration router, a respective image file of the plurality of image files to a respective die of the plurality of dies based on an identifier of the respective die and an identifier of the respective image file, wherein the routing of the respective image file occurs via a pathway corresponding to the second protocol.
